(19) United States
(12) Patent Application Publication
(10) Pub. No.: US 2024/0339381 A1
(43) Pub. Date: Oct. 10, 2024

(54) AIR-GAP TRACES AND AIR-GAP EMBEDDED BRIDGE INTEGRATED IN GLASS INTERPOSER

(71) Applicant: Intel Corporation, Santa Clara, CA (US)

(72) Inventors: Hiroki TANAKA, Gilbert, AZ (US); Veronica STRONG, Hillsboro, OR (US); Henning BRAUNISCH, Phoenix, AZ (US); Haobo CHEN, Gilbert, AZ (US); Jeremy D. ECTON, Gilbert, AZ (US); Kristof DARMAWIKARTA, Chandler, AZ (US); Brandon C. MARIN, Gilbert, AZ (US)

(21) Appl. No.: 18/130,582

(22) Filed: Apr. 4, 2023

(51) Int. Cl. H01L 23/482; H01L 21/768; H01L 23/498

(52) U.S. Cl. CPC H01L 23/4821; H01L 21/76831; H01L 23/49827; H01L 23/49866; H01L 21/30604; H05K 2201/09218

(57) ABSTRACT

Embodiments disclosed herein include an interposer. In an embodiment, the interposer comprises a substrate, where the substrate comprises a glass layer. In an embodiment, a trace is on the substrate, where the trace has a bottom surface, sidewall surfaces, and a top surface. In an embodiment, the sidewall surfaces and the top surface are exposed to air. In an embodiment, a trench into the substrate is adjacent to at least one sidewall surface of the trace.

### TECHNICAL FIELD

Embodiments of the present disclosure relate to electronic systems, and more particularly to glass interposers with high density traces that are surrounded by an air-gap.

### BACKGROUND

Increasing input/output (I/O) density can have a significant impact on the resistance-capacitance (RC) delay, crosstalk, and dynamic power consumption. To reduce RC delay, one can use dielectric materials with a low relative dielectric constant k. Such dielectric materials may sometimes be referred to as low-k dielectrics or ultra-low-k dielectrics. Providing low-k materials around the electrically conductive traces results in improvements to capacitance and cross-talk coefficient (k_{b}). However, there are material limits as to how low the dielectric constant can be made. For example, ultra-low-k dielectrics may not have suitable mechanical properties, which can lead to reliability concerns for the device. Additionally, low-k and ultra-low-k dielectrics can be more expensive than traditional buildup film materials, which increases the cost of the system.

As electronic packaging integration continues to smaller line width and spacing (i.e., L/S), such electrical issues become even more significant. For example, in some bridge type architectures (e.g., embedded bridge structures), high density L/S values are needed in order to provide the necessary bandwidth between a pair of dies. For example, L/S dimensions may approach approximately 2 μm/2 μm or smaller in some solutions. Further, bridge architectures that are formed with glass substrates have seen little investigation in how to improve electrical properties of the high density L/S structures.

### BRIEF DESCRIPTION OF THE DRAWINGS

FIG. 1A is a cross-sectional illustration of a bridge with high density traces that are surrounded by an air-gap, in accordance with an embodiment.

FIG. 1B is a cross-sectional illustration of a bridge with multiple layers of high density traces that are surrounded by an air-gap, in accordance with an embodiment.

FIGS. 2A-2L are cross-sectional illustrations depicting a process for forming a bridge with traces that are surrounded by an air-gap, in accordance with an embodiment.

FIG. 3A is a cross-sectional illustration of a bridge with high density traces that are surrounded by an air gap with a spacer provided between glass layers, in accordance with an embodiment.

FIG. 3B is a cross-sectional illustration of a bridge with multiple layers of high density traces that are surrounded by an air-gap with spacers provided between glass layers, in accordance with an embodiment.

FIGS. 4A-4P are cross-sectional illustrations depicting a process for forming

a bridge with traces that are surrounded by an air-gap with spacers between glass layers, in accordance with an embodiment.

FIG. 5A is a cross-sectional illustration of a multi-die module that is coupled together by a bridge that is embedded in an interposer, in accordance with an embodiment.

FIG. 5B is a cross-sectional illustration of a multi-die module that is coupled together by a bridge on the interposer, in accordance with an embodiment.

FIG. 6 is a cross-sectional illustration of an electronic system that includes an embedded bridge in an interposer over a package substrate and board, in accordance with an embodiment.

FIG. 7 is a schematic of a computing device built in accordance with an embodiment.

### EMBODIMENTS OF THE PRESENT DISCLOSURE

Described herein are electronic systems, and more particularly, glass interposers with high density traces that are surrounded by an air-gap, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, high density routing for bridge like architectures suffer from poor electrical performance. For example, capacitance and cross-talk between traces is a limiting factor in many bridge architectures. Particularly, as L/S dimensions approach 2 μm/2 μm or lower, electrical performance suffers, even when low-k or ultra-low-k dielectrics are used. Accordingly, embodiments disclosed herein include the use air-gaps. Air has the lowest naturally occurring dielectric constant. As such, electrical performance is significantly improved.

In an embodiment, the air-gaps are formed through the generation of trenches adjacent to the traces. That is, a trench into the substrate is provided between each of the traces. An overlying substrate is then attached to the structure using a dielectric adhesive. The overlying substrate may be attached with a lamination process or pressing process that omits a vacuum. As such, the air-gap remains around the traces, and electrical performance is improved.

In an embodiment, the substrates used herein for the bridge structures may include any suitable rigid material. In a particular embodiment, the substrates may include glass. That is, the bridges described herein may be considered to be glass-based bridge structures. Though, other substrates materials may be used. In an embodiment, the bridge structures may include a single layer of air-gapped traces. In other embodiments, multiple layers of air-gapped traces may be implemented.

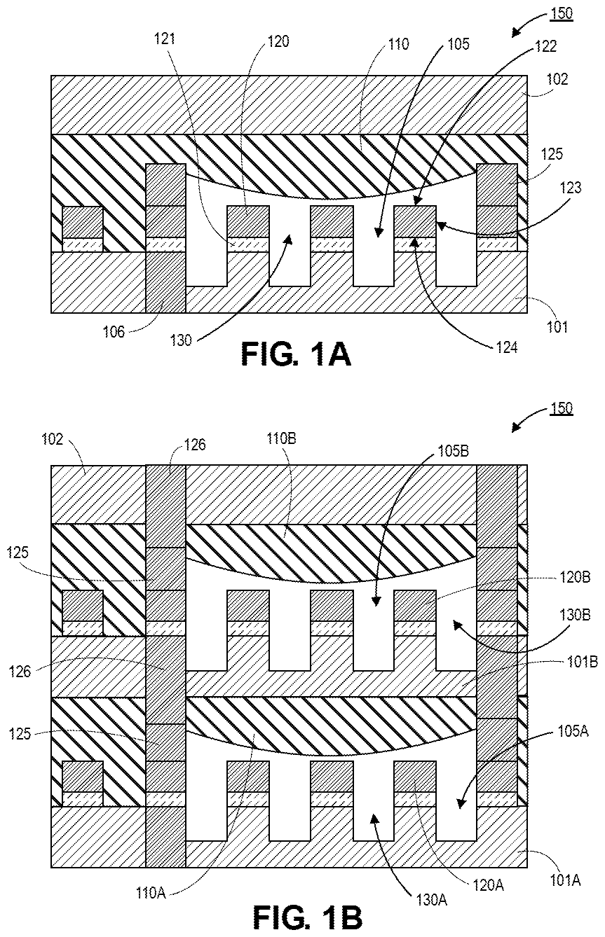

Referring now to FIG. 1A, a cross-sectional illustration of a single layer bridge 150 is shown, in accordance with an embodiment. While referred to as a bridge 150, the structure in FIG. 1A may be formed directly on an interposer in some embodiments instead of being a discrete component. In an embodiment, the bridge 150 comprises a first substrate 101. The first substrate 101 may comprise glass. The first substrate 101 may comprise substantially all glass or be considered a glass layer. In an embodiment, a conductive via 106 may be provided through the first substrate 101. The via 106 may couple the routing layer shown in FIG. 1A to underlying routing layers (not shown).

In an embodiment, a plurality of conductive features may be provided over seed layers 121. For example, traces 120 may be provided over the seed layers 121. Overlying vias 125 may be provided over some of the traces 120. The overlying vias 125 may be formed with a zero misalignment or a dual lithography plating process. As such, the overlying vias 125 may have substantially no misalignment with the underlying traces 120 in some embodiments. In an embodiment, the traces 120 may be high density traces. For example, a L/S dimension of the traces 120 may be approximately 5 μm/5 μm or less, or approximately 2 μm/2 μm or less. As used herein, “approximately” may refer to a range of values within ten percent of the stated value. For example, approximately 2um may refer to a range between 1.8 μm and 2.2 μm.

In an embodiment, trenches 105 may be provided between the traces 120. The trenches 105 may extend into a top surface of the first substrate 101. In an embodiment, the trenches 105 may extend halfway through the first substrate 101 or more. Though, shallower trenches 105 may also be used in some embodiments. As shown, the trenches 105 are aligned with the traces 120. That is, sidewalls 123 of the traces 120 are aligned with the sidewalls of the trenches 105. This is due to the traces 120 being used as the etch mask for the formation of the trenches.

In an embodiment, a second substrate 102 may be provided above the first substrate 101. The second substrate 102 may be the same material as the first substrate 101. For example, the second substrate 102 may comprise substantially all glass in some embodiments. In an embodiment, the second substrate 102 may be adhered to the structure through the use of a dielectric adhesive 110. For example, the adhesive 110 may contact the first substrate 101 outside of the high density trace 120 region. Vias 125 may serve as supports that prevent the dielectric adhesive 110 from filling the air-gap 130 around the traces 120. In some embodiments, the surface of the adhesive 110 may be curved above the traces 120.

In an embodiment, the air-gap 130 may be provided around the surfaces of the traces 120. For example, air may contact the top surface 122 and the sidewall surfaces 123 of the traces 120. The bottom surface 124 of the traces 120 may be provided in contact with the underlying seed layer 121. That is, the traces 120 may be referred to as having at least three surfaces that are exposed to air. Further, adjacent traces 120 may be separated by only air. That is, no solid material may be provided between sidewalls 123 of adjacent traces. The air-gap 130 enables improved electrical performance since air has a dielectric constant of approximately 1.0. For example, compared to existing low-k materials surrounding the traces 120, simulations illustrate improvements in capacitance of approximately 50% or greater and improvements in crosstalk of approximately 10% or greater when air-gapped solutions are used.

Referring now to FIG. 1B, a cross-sectional illustration of a multi-layer bridge 150 is shown, in accordance with an embodiment. In an embodiment, the multi-layer bridge 150 may include substrates 101A and 101B. The substrates 101A and 101B may be glass substrates. In an embodiment, trenches 105A may be formed into the substrate 101A, and trenches 105B may be formed into the substrate 101B. The trenches 105A may be between traces 120A, and the trenches 105B may be between traces 120B.

In an embodiment, vias 125 and 126 may provide electrical coupling between layers of the bridge 150. Additionally, dielectric adhesives 110A and 110B may be used to adhere substrates together. For example, adhesive 110A couples substrate 101B to substrate 101A, and adhesive 110B couples the substrate 102 to the substrate 101B. The adhesives 110A and 110B may also define a portion of the air-gaps 130A and 130B. The air-gaps 130A and 130B may provide improved electrical performance for the traces 120A and 120B.

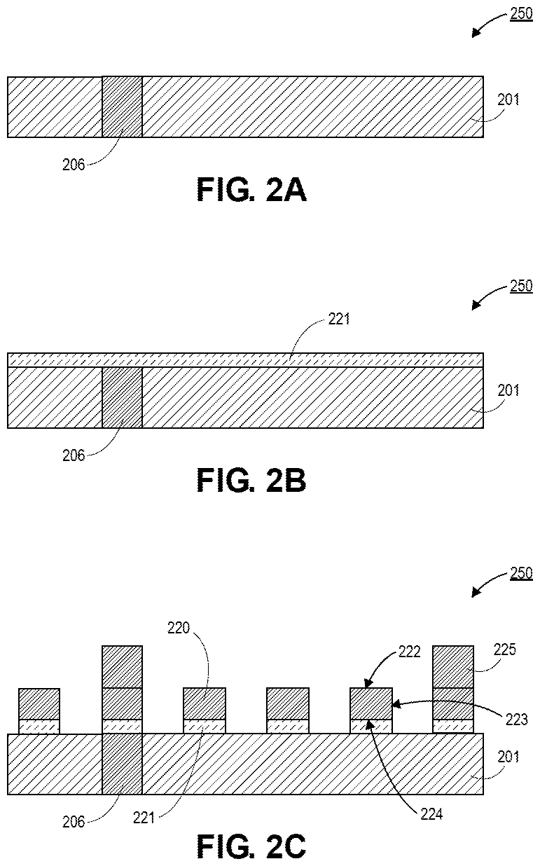

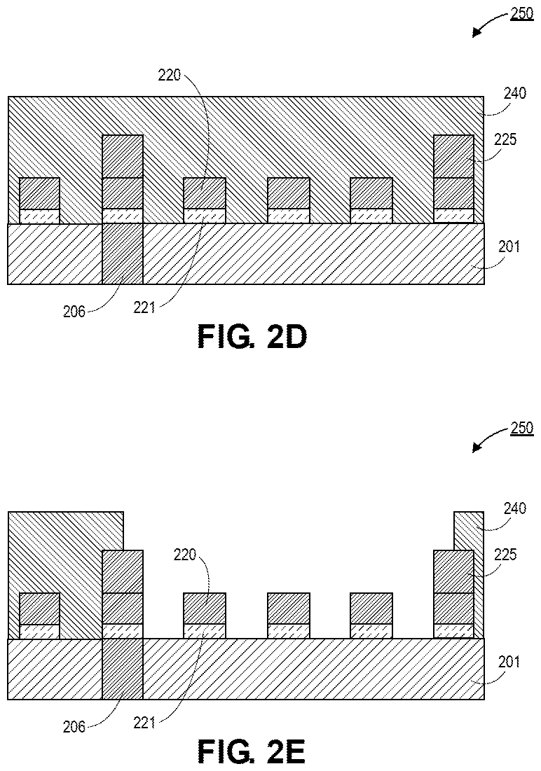

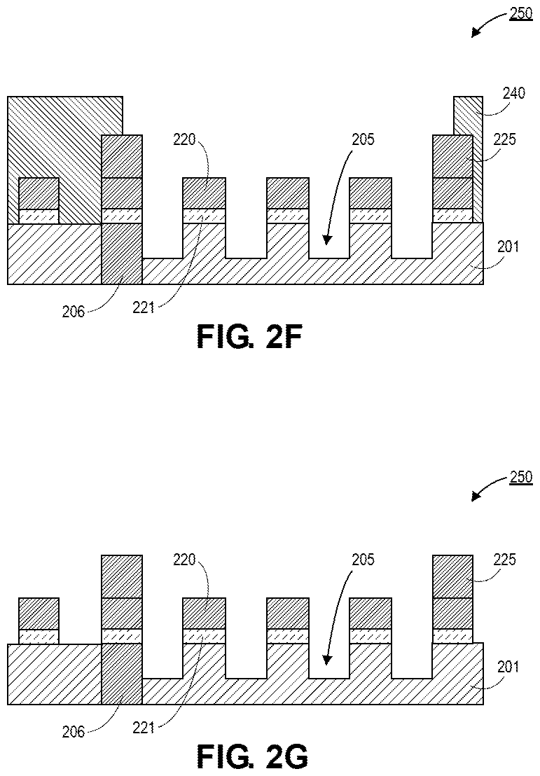

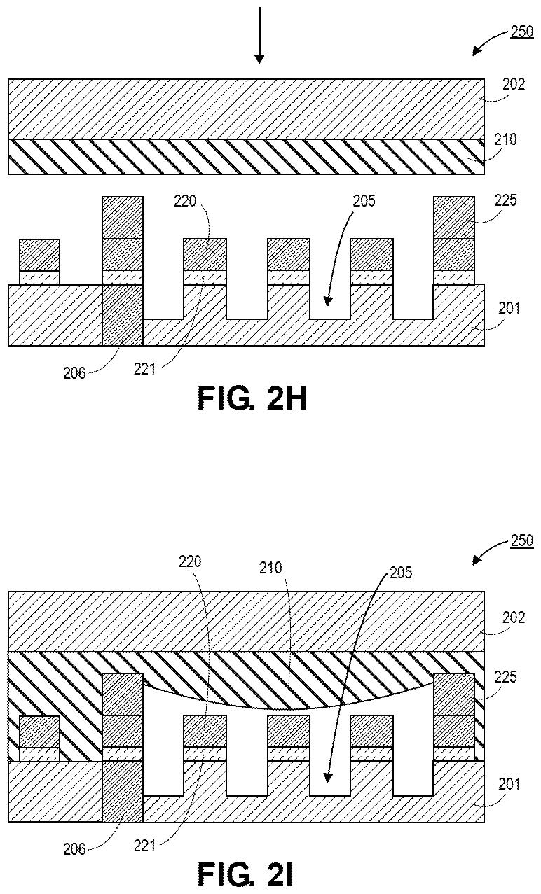

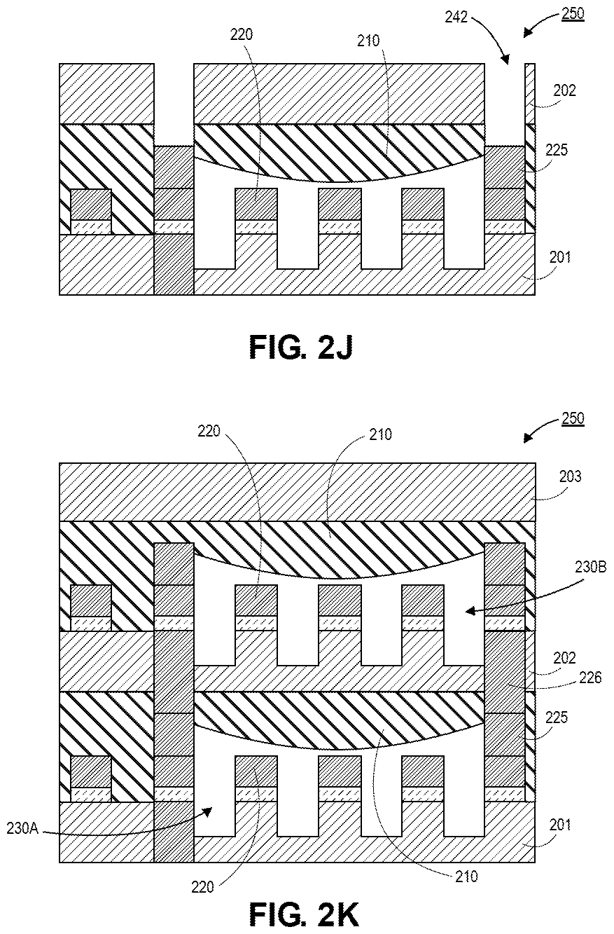

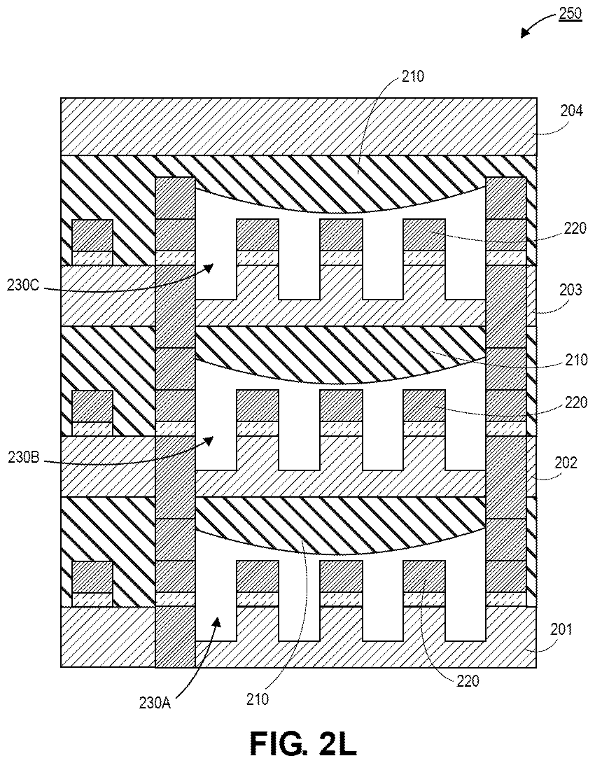

In the illustrated embodiment, the bridge 150 includes two layers of traces 120A and 120B. However, it is to be appreciated that any number of layers (i.e., one or more layers) may be included in the bridge 150. For example, processing flows, such as the one shown in FIGS. 2A-2L may be repeated any number of times in order to provide a desired number of routing layers for the bridge 150.

Referring now to FIGS. 2A-2L, a series of cross-sectional illustrations depicting a process for forming a bridge 250 is shown, in accordance with an embodiment. In an embodiment, the bridge 250 formed in FIGS. 2A-2L may be similar to one or both of the bridges 150 described in greater detail above.

Referring now to FIG. 2A, a cross-sectional illustration of the bridge 250 at a stage of manufacture is shown, in accordance with an embodiment. In an embodiment, the bridge 250 may comprise a first substrate 201. The first substrate 201 may include glass. For example, the first substrate 201 may be a glass layer in some embodiments. The first substrate 201 may have a thickness that is approximately 50 μm or greater, or approximately 1,000 μm or greater. In an embodiment, a via 206 may be provided through a thickness of the first substrate 201. The via 206 may be an electrically conductive material, such as copper. The via 206 may allow for electrical coupling of the bridge 250 to an underlying structure (not shown).

Referring now to FIG. 2B, a cross-sectional illustration of the bridge 250 after a seed layer 221 is applied is shown, in accordance with an embodiment. The seed layer 221 may be a blanket deposited electrically conductive layer. For example, the seed layer 221 may comprise titanium and/or copper. The seed layer 221 may have a thickness that is approximately 1 μm or less. In an embodiment, a blanket deposition process, such as physical vapor deposition (PVD), sputtering, chemical vapor deposition (CVD), or the like may be used in order to form the seed layer 221.

Referring now to FIG. 2C, a cross-sectional illustration of the bridge 250 after conductive features are formed over the first substrate 201 is shown, in accordance with an embodiment. The conductive features may include traces 220. The traces 220 may have a top surface 222, a bottom surface 224, and sidewall surfaces 223. In an embodiment, the traces 220 may have a L/S dimension that is approximately 5 μm /5 μm or less, or approximately 2 μm /2 μm or less. The traces 220 may be copper traces that are plated up from the seed layer 221. After plating the traces 220, the residual portions of the seed layer 221 that are not covered by the traces 220 are removed with an etching process. In an embodiment, vias 225 may be provided over a top surface of some of the traces 220. In an embodiment, the vias 225 may be formed with a zero-misalignment patterning process or a dual lithography process. As such, the vias 225 may be substantially aligned with the underlying traces 220. The vias 225 may be used for electrical coupling between layers of the bridge 250, and for a structure to tent a subsequently applied adhesive over the traces 220.

Referring now to FIG. 2D, a cross-sectional illustration of the bridge 250 after a resist layer 240 is applied over the structure is shown, in accordance with an embodiment. In an embodiment, the resist layer 240 may be a dry film resist (DFR) or any other suitable photolithography compatible resist material. In an embodiment, the resist layer 240 may be applied with a lamination process, or the like.

Referring now to FIG. 2E, a cross-sectional illustration of the bridge 250 after the resist 240 is patterned to form an opening 241 is shown, in accordance with an embodiment. The opening 241 may be formed with a lithography operation. The opening 241 may be provided over the high density traces 220 between the vias 225. That is, the opening 241 may be provided wherever trenches are desired.

Referring now to FIG. 2F, a cross-sectional illustration of the bridge 250 after trenches 205 are formed is shown, in accordance with an embodiment. In an embodiment, the trenches 205 may be formed with an etching process. For example, a wet or dry etching process may be used in order to etch into the first substrate 201. The presence of the traces 220 may also function as a mask layer. As such, the trenches 205 may be aligned with the edges of the traces 220. While shown as having substantially vertical sidewalls, the trenches 205 may have any shape consistent with the etching process used. For example, in the case of a wet etching process, the trenches may be rounded since a wet etch may not be as anisotropic as a dry etching process.

Referring now to FIG. 2G, a cross-sectional illustration of the bridge 250 after the resist 240 is stripped is shown, in accordance with an embodiment. In an embodiment, the resist 240 may be stripped or removed with any suitable process.

Referring now to FIG. 2H, a cross-sectional illustration of the bridge 250 during application of a second substrate 202 is shown, in accordance with an embodiment. In an embodiment, the second substrate 202 may be laminated or pressed onto the structure. A dielectric adhesive 210 may be provided on the bottom of the second substrate 202 in order to secure the two substrates 201 and 202 together. In an embodiment, the lamination or pressing process may be implemented without a vacuum, since a vacuum process may result in the air-gap being compromised. In an embodiment, the second substrate 202 may also comprise glass. For example, the second substrate 202 may be a glass layer.

Referring now to FIG. 2I, a cross-sectional illustration of the bridge 250 after the lamination or pressing process is completed is shown, in accordance with an embodiment. In an embodiment, the adhesive 210 may span across the traces 220. That is, the adhesive 210 may be tented above the traces 220. As such, an air-gap 230 is provided around the traces 220. For example, air contacts three or more sides of the traces 220. More generally, no solid material may be provided between sidewalls of adjacent traces 220.

Referring now to FIG. 2J, a cross-sectional illustration of the bridge 250 after via openings 242 are formed through the second substrate 202 is shown, in accordance with an embodiment. In an embodiment, the via openings 242 may be provided over the vias 225. The via openings 242 may be formed with a lithography patterning and etching process.

Referring now to FIG. 2K, a cross-sectional illustration of the bridge 250 after a second layer of traces 220 is provided over the first layer of traces 220 is shown, in accordance with an embodiment. As shown, vias 226 are provided in the via openings 242, and the processing described with respect to FIGS. 2A-2I may be repeated in order to form the second layer of traces 220. Accordingly, a first air-gap 230A is provided around the first layer of traces 220, and a second air-gap 230B is provided around the second layer of traces 220. A third substrate 203 may be provided over the second substrate 202.

Referring now to FIG. 2L, a cross-sectional illustration of the bridge 250 after a third layer of traces 220 is provided is shown, in accordance with an embodiment. The third layer of traces 220 may be within an air-gap 230C. The third layer may be formed by repeating the processing operations described above. In the illustrated embodiment, three layers of traces 220 are shown. Though, it is to be appreciated that embodiments may include a single layer of traces 220 (e.g., stopping the process at FIG. 21), or embodiments may include two or more layers of traces 220. Additional layers may be provided by repeating the process flow any number of times.

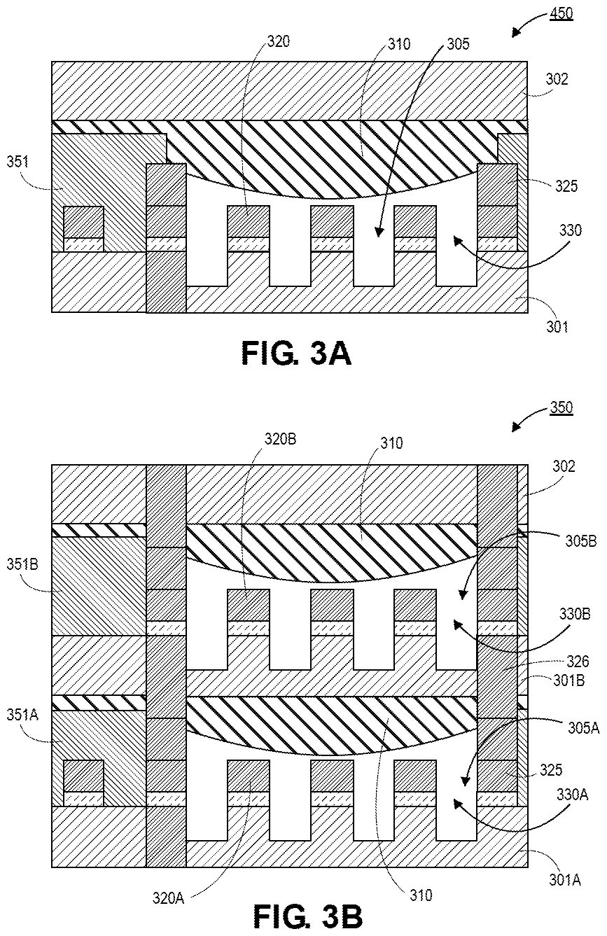

Referring now to FIG. 3A, a cross-sectional illustration of a bridge 350 is shown, in accordance with an additional embodiment. While referred to as a bridge 350, the structure in FIG. 3A may be formed directly on an interposer in some embodiments instead of being a discrete component. In an embodiment, the bridge 350 comprises a first substrate 301. The first substrate 301 may comprise glass. The first substrate 301 may comprise substantially all glass or be considered a glass layer.

In an embodiment, a plurality of conductive features may be provided over seed layers 321. For example, traces 320 may be provided over the seed layers 321. Overlying vias 325 may be provided over some of the traces 320. The overlying vias 325 may be formed with a zero misalignment or a dual lithography plating process. As such, the overlying vias 325 may have substantially no misalignment with the underlying traces 320 in some embodiments. In an embodiment, the traces 320 may be high density traces.

For example, a L/S dimension of the traces 320 may be approximately 5 μm/5 μm or less, or approximately 2 μm/2 m or less.

In an embodiment, trenches 305 may be provided between the traces 320. The trenches 305 may extend into a top surface of the first substrate 301. In an embodiment, the trenches 305 may extend halfway through the first substrate 301 or more. Though, shallower trenches 305 may also be used in some embodiments. As shown, the trenches 305 are aligned with the traces 320. That is, sidewalls of the traces 320 are aligned with the sidewalls of the trenches 305. This is due to the traces 320 being used as the etch mask for the formation of the trenches.

In an embodiment, a second substrate 302 may be provided above the first substrate 301. The second substrate 302 may be the same material as the first substrate 301. For example, the second substrate 302 may comprise substantially all glass in some embodiments. In an embodiment, the second substrate 302 may be adhered to the structure through the use of a dielectric adhesive 310. For example, the adhesive 310 may contact spacers 351 outside of the high density traces 320. In an embodiment, the spacers 351 may be supports that prevent the dielectric adhesive 310 from filling the air-gap 330 around the traces 320. The spacers 351 may also provide improved adhesion strength between the layers. As such, mechanical reliability may be improved compared to embodiments described in greater detail above. In some embodiments, the surface of the adhesive 310 may be curved above the traces 320.

In an embodiment, the air-gap 330 may be provided around the surfaces of the traces 320. For example, air may contact the top surface and the sidewall surfaces of the traces 320. The bottom surface of the traces 320 may be provided in contact with the underlying seed layer 321. That is, the traces 320 may be referred to as having at least three surfaces that are exposed to air. Further, adjacent traces 320 may be separated by only air. That is, no solid material may be provided between sidewalls of adjacent traces. The air-gap 330 enables improved electrical performance since air has a dielectric constant of approximately 1.0. For example, compared to existing low-k materials surrounding the traces 320, simulations illustrate improvements in capacitance of approximately 50% or greater and improvements in crosstalk of approximately 10% or greater when air-gapped solutions are used.

Referring now to FIG. 3B, a cross-sectional illustration of a multi-layer bridge 350 is shown, in accordance with an embodiment. In an embodiment, the multi-layer bridge 350 may include substrates 301A and 301B. The substrates 301A and 301B may be glass substrates. In an embodiment, trenches 305A may be formed into the substrate 301A, and trenches 305B may be formed into the substrate 301B. The trenches 305A may be between traces 320A, and the trenches 305B may be between traces 320B.

In an embodiment, vias 325 and 326 may provide electrical coupling between layers of the bridge 350. Additionally, dielectric adhesives 310 may be used to adhere substrates together. Outside of the traces 320A and 320B, the adhesives 310 may be coupled to spacers 351A and 351B. The adhesives 310 may also define a portion of the air-gaps 330A and 330B. The air-gaps 330A and 330B may provide improved electrical performance for the traces 320A and 320B.

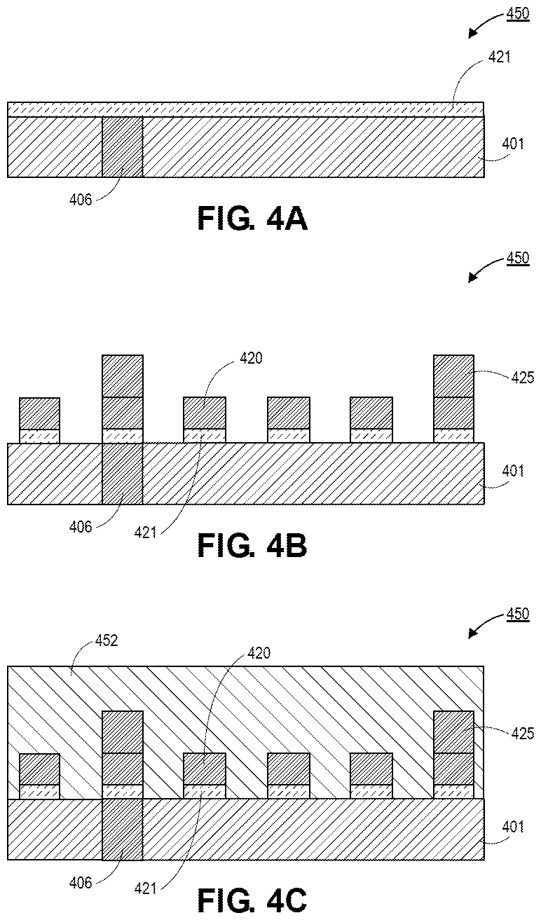

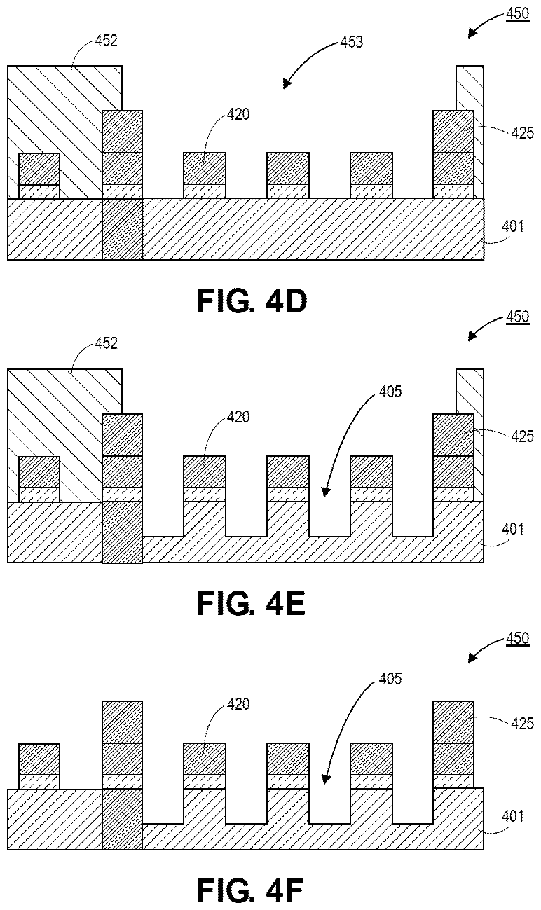

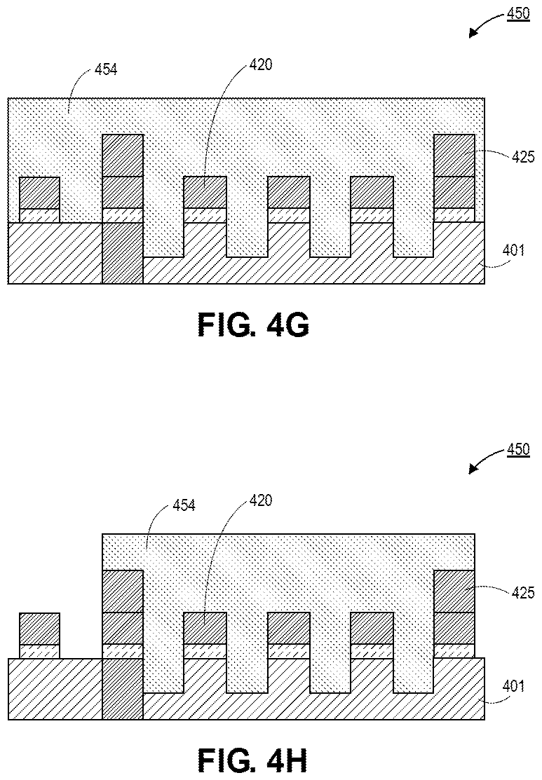

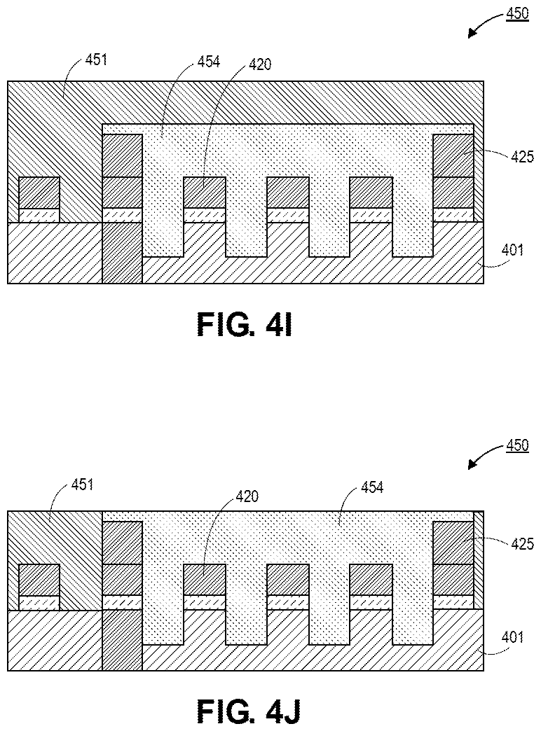

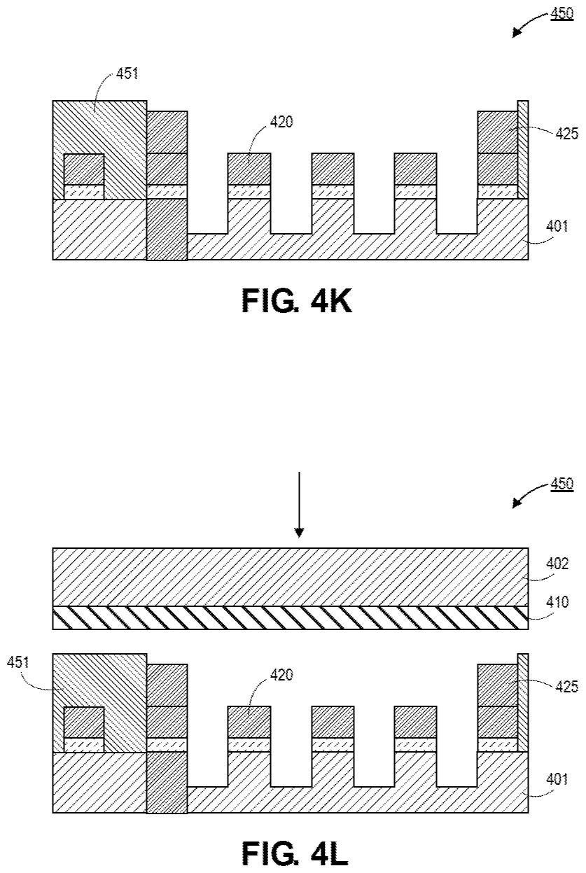

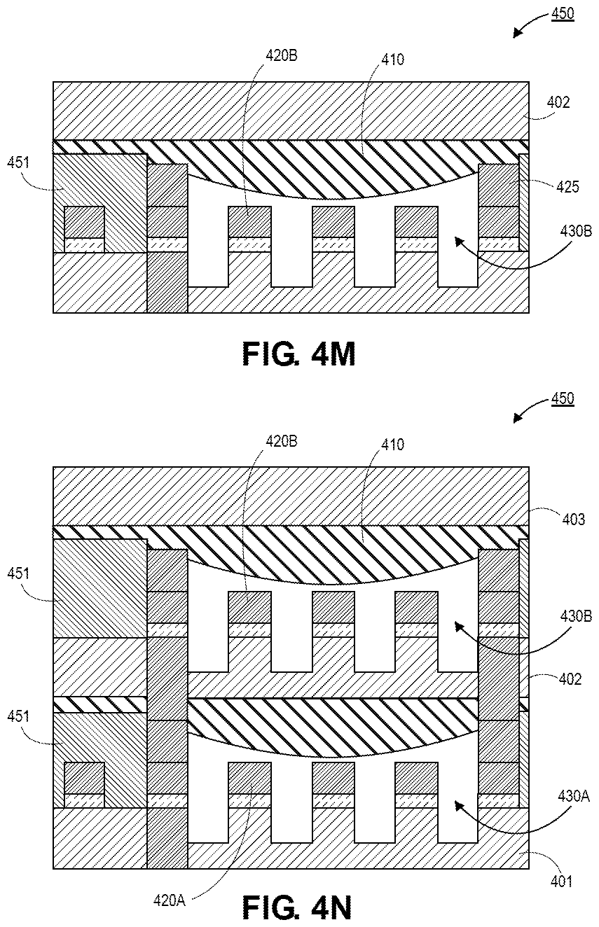

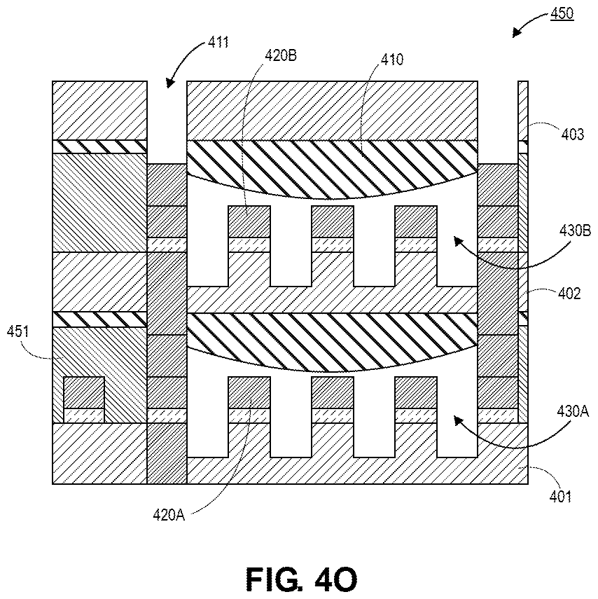

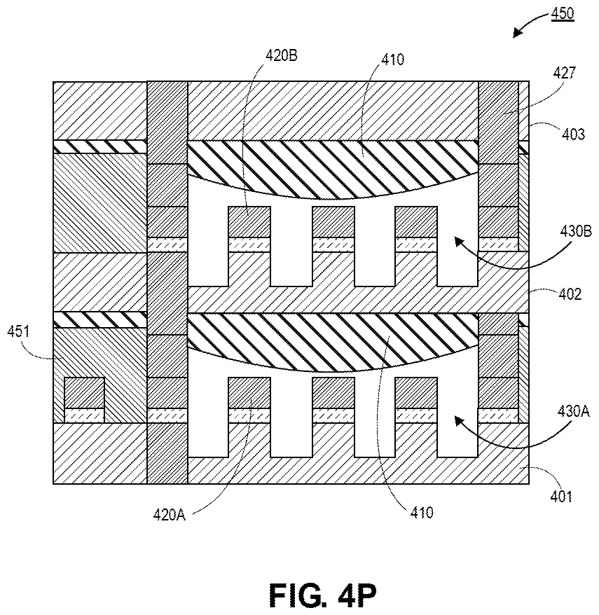

In the illustrated embodiment, the bridge 350 includes two layers of traces 320A and 320B. However, it is to be appreciated that any number of layers (i.e., one or more layers) may be included in the bridge 350. For example, processing flows, such as the one shown in FIGS. 4A-4P may be repeated any number of times in order to provide a desired number of routing layers for the bridge 350.

Referring now to FIGS. 4A-4P, a series of cross-sectional illustrations depicting a process for forming a bridge 450 is shown, in accordance with an embodiment. In an embodiment, the bridge 450 formed in FIGS. 4A-4P may be similar to one or both of the bridges 350 described in greater detail above.

Referring now to FIG. 4A, a cross-sectional illustration of the bridge 450 at a stage of manufacture is shown, in accordance with an embodiment. In an embodiment, the bridge 450 may comprise a first substrate 401. The first substrate 401 may include glass. For example, the first substrate 401 may be a glass layer in some embodiments. The first substrate 401 may have a thickness that is approximately 50 μm or greater, or approximately 1,000 μm or greater. In an embodiment, a via 406 may be provided through a thickness of the first substrate 401. The via 406 may be an electrically conductive material, such as copper. The via 406 may allow for electrical coupling of the bridge 450 to an underlying structure (not shown).

In an embodiment, a seed layer 421 is applied over the first substrate 401. The seed layer 421 may be a blanket deposited electrically conductive layer. For example, the seed layer 421 may comprise titanium and/or copper. The seed layer 421 may have a thickness that is approximately 1 μm or less. In an embodiment, a blanket deposition process, such as PVD, sputtering, CVD, or the like may be used in order to form the seed layer 421.

Referring now to FIG. 4B, a cross-sectional illustration of the bridge 450 after conductive features are formed over the first substrate 401 is shown, in accordance with an embodiment. The conductive features may include traces 420. In an embodiment, the traces 420 may have a L/S dimension that is approximately 5 μm/5 μm or less, or approximately 2 μm/2 μm or less. The traces 420 may be copper traces that are plated up from the seed layer 421. After plating the traces 420, the residual portions of the seed layer 421 that are not covered by the traces 420 are removed with an etching process. In an embodiment, vias 425 may be provided over a top surface of some of the traces 420. In an embodiment, the vias 425 may be formed with a zero-misalignment patterning process or a dual lithography process. As such, the vias 425 may be substantially aligned with the underlying traces 420. The vias 425 may be used for electrical coupling between layers of the bridge 450.

Referring now to FIG. 4C, a cross-sectional illustration of the bridge 450 after a resist layer 452 is applied over the structure is shown, in accordance with an embodiment. In an embodiment, the resist layer 452 may be a DFR or any other suitable photolithography compatible resist material. In an embodiment, the resist layer 452 may be applied with a lamination process, or the like.

Referring now to FIG. 4D, a cross-sectional illustration of the bridge 450 after the resist 452 is patterned to form an opening 453 is shown, in accordance with an embodiment. The opening 453 may be formed with a lithography operation. The opening 453 may be provided over the high density traces 420 between the vias 425. That is, the opening 453 may be provided wherever trenches are desired.

Referring now to FIG. 4E, a cross-sectional illustration of the bridge 450 after trenches 405 are formed is shown, in accordance with an embodiment. In an embodiment, the trenches 405 may be formed with an etching process. For example, a wet or dry etching process may be used in order to etch into the first substrate 401. The presence of the traces 420 may also function as a mask layer. As such, the trenches 405 may be aligned with the edges of the traces 420. While shown as having substantially vertical sidewalls, the trenches 405 may have any shape consistent with the etching process used. For example, in the case of a wet etching process, the trenches may be rounded since a wet etch may not be as anisotropic as a dry etching process.

Referring now to FIG. 4F, a cross-sectional illustration of the bridge 450 after the resist 452 is stripped is shown, in accordance with an embodiment. In an embodiment, the resist 452 may be stripped or removed with any suitable process.

Referring now to FIG. 4G, a cross-sectional illustration of the bridge 450 after a DFR 454 is applied over the structure is shown, in accordance with an embodiment. In an embodiment, the DFR 454 may be applied with a lamination process or the like.

Referring now to FIG. 4H, a cross-sectional illustration of the bridge 450 after the DFR 454 is patterned is shown, in accordance with an embodiment. In an embodiment, the DFR 454 may be patterned so that openings outside of the high density traces 420 are formed. That is, the DFR 454 may persist over the high density traces 420.

Referring now to FIG. 4I, a cross-sectional illustration of the bridge 450 after a spacer 451 is deposited is shown, in accordance with an embodiment. In an embodiment, the spacer 451 may be a dielectric material, such as an organic buildup film or the like. In an embodiment, the spacer 451 may be deposited with a lamination process or the like. The spacer 451 may be provided over a top surface of the DFR 454.

Referring now to FIG. 4J, a cross-sectional illustration of the bridge 450 after a polishing process is shown, in accordance with an embodiment. In an embodiment, a polishing process, such as chemical mechanical polishing (CMP), is used to reduce the thickness of the spacer 451 until the top surface of the DFR 454 is exposed.

Referring now to FIG. 4K, a cross-sectional illustration of the bridge 450 after the DFR 454 is removed is shown, in accordance with an embodiment. In an embodiment, the DFR 454 is removed with a stripping process, or the like. The removal of the DFR 454 exposes the traces 420.

Referring now to FIG. 4L, a cross-sectional illustration of the bridge 450 during application of a second substrate 402 is shown, in accordance with an embodiment. In an embodiment, the second substrate 402 may be laminated or pressed onto the structure. A dielectric adhesive 410 may be provided on the bottom of the second substrate 402 in order to secure the two substrates 401 and 402 together. In an embodiment, the lamination or pressing process may be implemented without a vacuum, since a vacuum process may result in the air-gap being compromised. In an embodiment, the second substrate 402 may also comprise glass. For example, the second substrate 402 may be a glass layer.

Referring now to FIG. 4M, a cross-sectional illustration of the bridge 450 after the lamination or pressing process is completed is shown, in accordance with an embodiment. In an embodiment, the adhesive 410 may span across the traces 420. That is, the adhesive 410 may be tented above the traces 420. More particularly, the spacers 451 may be used to support the adhesive 410 above the traces 420 and to improve coupling strength between the substrates 401 and 402. As such, an air-gap 430 is provided around the traces 420. For example, air contacts three or more sides of the traces 420. More generally, no solid material may be provided between sidewalls of adjacent traces 420.

Referring now to FIG. 4N, a cross-sectional illustration of the bridge 450 after a second layer of traces 420B is provided over the first layer of traces 420A is shown, in accordance with an embodiment. The first layer of traces 420A may be in a first air-gap 430A, and the second layer of traces 420B may be in a second air-gap 430B. A third substrate 403 may be provided above the second substrate 402. An adhesive dielectric 410 and spacers 451 may couple the third substrate 403 to the second substrate 402. In an embodiment, the second layer may be formed with processes similar to those described above with respect to FIGS. 4A-4M.

Referring now to FIG. 4O, a cross-sectional illustration of the bridge 450 after via openings 411 are formed through the third substrate 403 is shown, in accordance with an embodiment. In an embodiment, the via openings 411 may be formed with a photolithography and patterning process.

Referring now to FIG. 4P, a cross-sectional illustration of the bridge 450 after vias 427 are formed in the via openings 411 is shown, in accordance with an embodiment. After the vias 427 are formed, processing may continue by repeating the processing operations above in order to make one or more additional layers (each with air-gapped traces) above the second layer of traces 420B. It is to be appreciated that embodiments include bridges 450 with any number of layers of air-gapped traces.

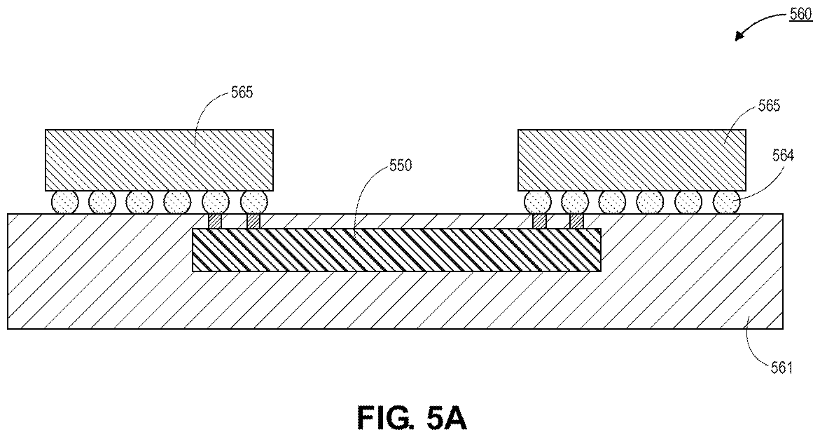

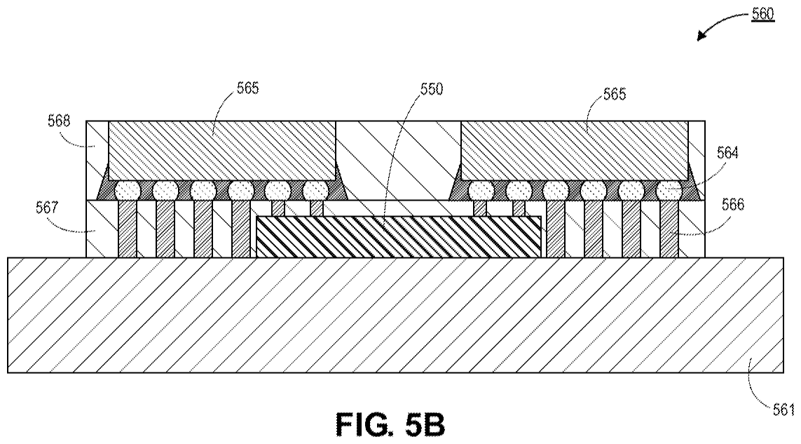

Referring now to FIG. 5A, a cross-sectional illustration of a multi-die module 560 is shown, in accordance with an embodiment. In an embodiment, the multi- die module 560 may comprise an interposer 561. The interposer 561 may be any suitable material. For example, the interposer 561 may be a glass interposer or an organic interposer. The interposer 561 may include an embedded bridge 550. The embedded bridge 550 may be similar to any of the bridge architectures described in greater detail herein. For example, the bridge 550 may include high density traces that are air-gapped in order to provide improved electrical performance. The bridge 550 may include any number of layers of air-gapped traces. The bridge 550 may include glass layers for the various substrate layers.

In an embodiment, the bridge 550 may communicatively couple a pair of dies 565 together. The dies 565 may be coupled to the interposer 561 through first level interconnects (FLIs) 564, such as solder balls, copper bumps, or the like. In an embodiment, the dies 565 may be compute dies, such as a central processing unit (CPU), a graphics processing unit (GPU), an XPU, a system on a chip (SoC), a communications die, a memory die, or the like.

Referring now to FIG. 5B, a cross-sectional illustration of a multi-die module 560 is shown, in accordance with an additional embodiment. As shown, the multi-die module 560 may comprise an interposer 561. The interposer 561 may be any suitable material. For example, the interposer 561 may be a glass interposer or an organic interposer. The interposer 561 may also be a package substrate (e.g., with or without a core). In an embodiment, a bridge 550 is provided over the interposer 561. The bridge 550 may be similar to any of the bridge architectures described in greater detail herein. For example, the bridge 550 may include high density traces that are air-gapped in order to provide improved electrical performance. The bridge 550 may include any number of layers of air-gapped traces. The bridge 550 may include glass layers for the various substrate layers.

In an embodiment, the bridge 550 may communicatively couple a pair of dies 565 together. The dies 565 may be coupled to the interposer 561 through first level interconnects (FLIs) 564, such as solder balls, copper bumps, or the like. In an embodiment, the dies 565 may be compute dies, such as a central processing unit (CPU), a graphics processing unit (GPU), an XPU, a system on a chip (SoC), a communications die, a memory die, or the like. The dies 565 may be coupled to the interposer 561 through pillars 566, such as copper pillars. In an embodiment, the FLIs 564 may be surrounded by an underfill. Mold layer 567 may be provided around the pillars 566 and the bridge 550. In an embodiment, mold layer 568 may be provided around the dies 565.

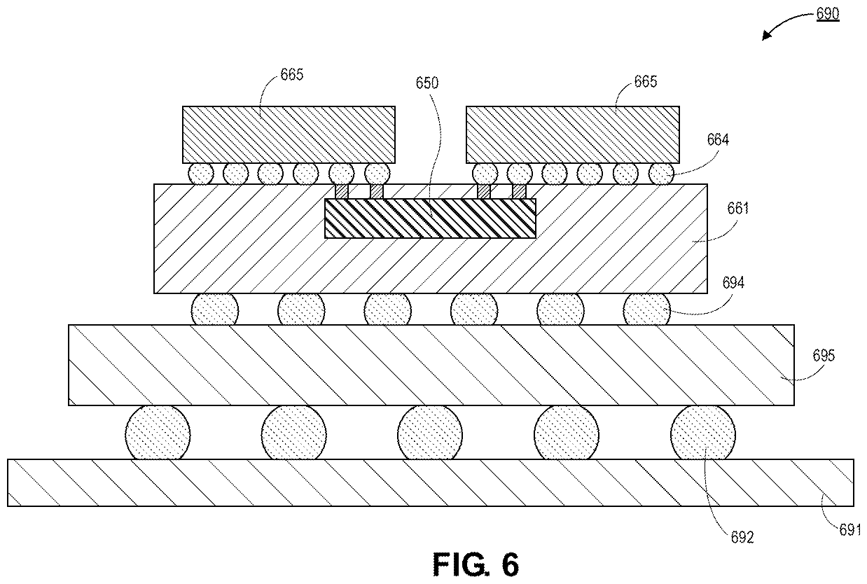

Referring now to FIG. 6, a cross-sectional illustration of an electronic system 690 is shown, in accordance with an embodiment. In an embodiment, the electronic system 690 comprises a board 691, such as a printed circuit board (PCB). In an embodiment, a package substrate 695 is coupled to the board 691 by interconnects 692. The interconnects 692 may be solder balls, sockets, or the like.

In an embodiment, the package substrate 695 may be coupled to an interposer 661 by interconnects 694, such as solder balls or the like. In an embodiment, the interposer 661 may be an organic interposer or a glass interposer. A bridge 650 may be embedded in the interposer 661. The bridge 650 may be similar to any of the bridge architectures described in greater detail herein. For example, the bridge 650 may include one or more air-gapped layers of high density traces. The bridge 650 may include one or more glass layers.

In an embodiment, the bridge 650 may communicatively couple together a pair of dies 665. The dies 665 may be coupled to the interposer 661 through interconnects 664. The interconnects 664 may be any suitable FLI architecture. The dies 665 may be compute dies similar to those described in greater detail above.

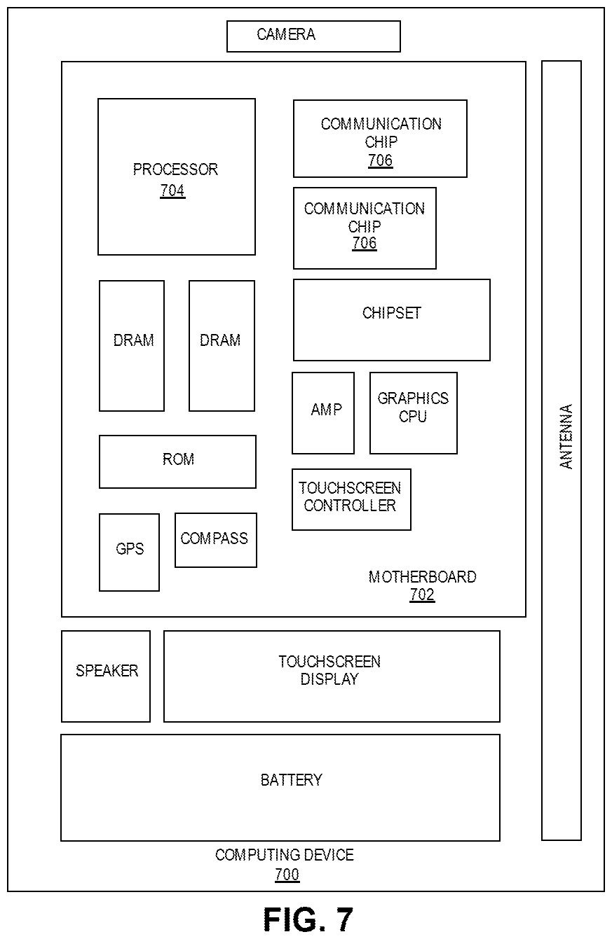

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor may be part of an electronic package that comprises an interposer with an embedded bridge that includes air-gapped high density traces, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip may be part of an electronic package that comprises an interposer with an embedded bridge that includes air-gapped high density traces, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 700 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an apparatus, comprising: a substrate, wherein the substrate comprises a glass layer; a trace on the substrate, wherein the trace has a bottom surface, sidewall surfaces, and a top surface, and wherein the sidewall surfaces and the top surface are exposed to air; and a trench into the substrate adjacent to at least one sidewall surface of the trace.

Example 2: the apparatus of Example 1, wherein a metallic layer is provided

between the trace and the substrate.

Example 3: the apparatus of Example 2, wherein the metallic layer is a seed layer comprising titanium and/or copper.

Example 4: the apparatus of Examples 1-3, wherein a via is provided over the

trace.

Example 5: the apparatus of Example 4, wherein the via has zero misalignment with the trace.

Example 6: the apparatus of Examples 1-5, further comprising: a second substrate over the first substrate, wherein the second substrate comprises a second glass layer; and a layer comprising a dielectric between the substrate and the second substrate.

Example 7: the apparatus of Example 6, wherein an air-gap is provided around the sidewalls and top surface of the trace, wherein outer surfaces of the air-gap are defined, at least in part, by the layer comprising the dielectric and the substrate.

Example 8: the apparatus of Example 6, wherein a spacer is provided between the substrate and the layer comprising the dielectric.

Example 9: the apparatus of Examples 1-8, further comprising: a plurality of

traces on the substrate.

Example 10: the apparatus of Example 9, wherein the traces have a trace width up to approximately 2 μm and a spacing between traces up to approximately 2 μm.

Example 11: a multi-die module, comprising: an interposer; a first die on the interposer; a second die on the interposer; and a bridge on the interposer, wherein the bridge communicatively couples the first die to the second die, wherein the bridge comprises: a first substrate comprising a first glass layer; first traces on the first substrate; a layer above the first traces; a second substrate comprising a second glass layer over the layer; and second traces on the second substrate.

Example 12: the multi-die module of Example 11, wherein air-gaps surround the first traces and the second traces.

Example 13: the multi-die module of Example 11 or Example 12, wherein the layer comprises a dielectric.

Example 14: the multi-die module of Examples 11-13, wherein a via is provided between the first traces and the second traces.

Example 15: the multi-die module of Examples 11-14, wherein trenches into the first substrate are adjacent to the sidewalls of the first traces.

Example 16: the multi-die module of Examples 11-15, wherein the interposer is an organic interposer or a glass interposer.

Example 17: the multi-die module of Examples 11-16, wherein the first traces and the second traces have a trace width of up to approximately 2um and a trace spacing of up to approximately 2um.

Example 18: an electronic system, comprising: a board; a package substrate coupled to the board; an interposer coupled to the package substrate; a bridge on the interposer, wherein the bridge comprises: a glass substrate with traces that are surrounded by air-gaps; and a pair of dies communicatively coupled to each other through the bridge.

Example 19: the electronic system of Example 18, wherein trenches into the glass substrates are adjacent to the traces.

Example 20: the electronic system of Example 18 or Example 19, wherein the electronic system is part of a personal computer, a server, a mobile device, a tablet, or an automobile.

What is claimed is:

1. An apparatus, comprising:
a substrate, wherein the substrate comprises a glass layer;
a trace on the substrate, wherein the trace has a bottom surface, sidewall surfaces, and a top surface, and wherein the sidewall surfaces and the top surface are exposed to air; and
a trench into the substrate adjacent to at least one sidewall surface of the trace.

2. The apparatus of claim 1, wherein a metallic layer is provided between the trace and the substrate.

3. The apparatus of claim 2, wherein the metallic layer is a seed layer comprising titanium and/or copper.

4. The apparatus of claim 1, wherein a via is provided over the trace.

5. The apparatus of claim 4, wherein the via has zero misalignment with the trace.

6. The apparatus of claim 1, further comprising:
a second substrate over the first substrate, wherein the second substrate comprises a second glass layer; and
a layer comprising a dielectric between the substrate and the second substrate.

7. The apparatus of claim 6, wherein an air-gap is provided around the sidewalls and top surface of the trace, wherein outer surfaces of the air-gap are defined, at least in part, by the layer comprising the dielectric and the substrate.

8. The apparatus of claim 6, wherein a spacer is provided between the substrate and the layer comprising the dielectric.

9. The apparatus of claim 1, further comprising:
a plurality of traces on the substrate.

10. The apparatus of claim 9, wherein the traces have a trace width up to approximately 2 μm and a spacing between traces up to approximately 2 μm.

11. A multi-die module, comprising:
an interposer;
a first die on the interposer;
a second die on the interposer; and
a bridge on the interposer, wherein the bridge communicatively couples the first die to the second die, wherein the bridge comprises:
a first substrate comprising a first glass layer;
first traces on the first substrate;
a layer above the first traces;
a second substrate comprising a second glass layer over the layer; and
second traces on the second substrate.

12. The multi-die module of claim 11, wherein air-gaps surround the first traces and the second traces.

13. The multi-die module of claim 11, wherein the layer comprises a dielectric.

14. The multi-die module of claim 11, wherein a via is provided between the first traces and the second traces.

15. The multi-die module of claim 11, wherein trenches into the first substrate are adjacent to the sidewalls of the first traces.

16. The multi-die module of claim 11, wherein the interposer is an organic interposer or a glass interposer.

17. The multi-die module of claim 11, wherein the first traces and the second traces have a trace width of up to approximately 2 μm and a trace spacing of up to approximately 2 μm.

18. An electronic system, comprising:
a board;
a package substrate coupled to the board;
an interposer coupled to the package substrate;
a bridge on the interposer, wherein the bridge comprises:
a glass substrate with traces that are surrounded by air-gaps; and
a pair of dies communicatively coupled to each other through the bridge.

19. The electronic system of claim 18, wherein trenches into the glass substrates are adjacent to the traces.

20. The electronic system of claim 18, wherein the electronic system is part of a personal computer, a server, a mobile device, a tablet, or an automobile.
